(19) United States
(12) Patent Application Publication
(10) Pub. No.: US 2012/0305955 A1
(43) Pub. Date: Dec. 6, 2012

(54) Luminescent Particles, Methods and Light Emitting Devices Including the Same

(76) Inventors: Christopher P. Hussell, Cary, NC (US); Brian Thomas Collins, Holly Springs, NC (US)

(21) Appl. No.: 13/149,048

(22) Filed: May 31, 2011

(51) Int. Cl. H01L 33/50; C23C 16/52; C09K 11/59; G01K 11/00; C09K 11/80

(52) U.S. Cl. 257/98; 374/161; 252/301.4 R; 252/301.4 F; 427/8; 257/E33.061; 374/E11.001

(57) ABSTRACT

A luminescent particle includes a luminescent compound that is configured to perform a photon down conversion on a portion of received light. The luminescent compound includes a host compound material and an activator material that is combined with the host compound material. The activator material is provided in a quantity that limits a conversion efficiency of the luminescent compound to limit a decrease in the decrease in luminous intensity of light emitted from the luminescent compound and thus provide a given color shift of the a combined emission wavelength from a non-excited state to a steady-state excited condition.

### BACKGROUND

The present invention relates to luminescent particles and light emitting devices including the same. More particularly, the present invention relates to luminescent particles that may be useful in light emitting devices.

Light emitting diodes and laser diodes are well known solid state lighting elements capable of generating light upon application of a sufficient voltage. Light emitting diodes and laser diodes may be generally referred to as light emitting diodes (“LEDs”). LEDs generally include a p-n junction formed in an epitaxial layer grown on a substrate such as sapphire, silicon, silicon carbide, gallium arsenide and the like. The wavelength distribution of the light generated by the LED generally depends on the material from which the p-n junction is fabricated and the structure of the thin epitaxial layers that make up the active region of the device.

LEDs may be used in devices to provide, for example, display backlighting. LEDs may also be used in lighting/illumination applications, for example, as a replacement for conventional incandescent and/or fluorescent lighting. In some lighting applications, it may be desirable to provide a lighting source that generates light having specific properties. For example, it may be desirable to provide a lighting source that generates white light having a relatively high color rendering index (CRI) so that objects illuminated by the lighting may appear more natural. The color rendering index of a light source is an objective measure of the ability of the light generated by the source to accurately illuminate a broad range of colors. The color rendering index ranges from essentially zero for monochromatic sources to nearly 100 for incandescent sources.

In addition, the chromaticity of a particular light source may be referred to as the “color point” of the source. For a white light source, the chromaticity may be referred to as the “white point” of the source. The white point of a white light source may fall along a locus of chromaticity points corresponding to the color of light emitted by a black-body radiator heated to a given temperature. Accordingly, a white point may be identified by a correlated color temperature (CCT) of the light source, which is the temperature at which the heated black-body radiator matches the color or hue of the white light source. White light typically has a CCT of between about 4000 and 8000K. White light with a CCT of 4000 has a yellowish color. White light with a CCT of 8000K is more bluish in color, and may be referred to as “cool white”. “Warm white” may be used to describe white light with a CCT of between about 2500K and 3500K, which is more reddish in color.

In order to produce white light, multiple LEDs emitting light of different colors of light may be used. The light emitted by the LEDs may be combined to produce a desired intensity and/or color of white light. For example, when red-, green- and blue-emitting LEDs are energized simultaneously, the resulting combined light may appear white, or nearly white, depending on the relative intensities of the component red, green and blue sources. However, in LED lamps including red, green, and blue LEDs, the spectral power distributions of the component LEDs may be relatively narrow (e.g., about 10-30 nm full width at half maximum (FWHM)). While it may be possible to achieve fairly high luminous efficacy and/or color rendering with such lamps, wavelength ranges may exist in which it may be difficult to obtain high efficiency (e.g., approximately 550 nm).

In addition, the light from a single-color LED may be converted to white light by surrounding the LED with a wavelength conversion material, such as a luminescent material. Some examples of luminescent materials may include, for example, materials described as phosphors and may include phosphor particles. A phosphor particle may refer to any material that absorbs light at one wavelength and re-emits light at a different wavelength, regardless of the delay between absorption and re-emission and regardless of the wavelengths involved. Accordingly, the term “phosphor” may be used herein to refer to materials that are sometimes called fluorescent and/or phosphorescent. In general, phosphors may absorb light having first wavelengths and re-emit light having second wavelengths that are different from the first wavelengths. For example, down conversion phosphors may absorb light having shorter wavelengths and re-emit light having longer wavelengths. As such, some or all of the light emitted by the LED at a first wavelength may be absorbed by the phosphor particles, which may responsively emit light at a second wavelength.

In operation, down conversion phosphors may generate undesirable heating. Such heating may result in performance changes including, for example, a change in the emitted color over time.

### SUMMARY

Some embodiments of the present invention include a luminescent particle that includes a luminescent compound that is configured to absorb a portion of received light and to emit light at an emission wavelength that is different from a wavelength of the portion of received light. The luminescent compound includes a host compound material and an activator material that is combined with the host compound material in a quantity that limits a conversion efficiency of the luminescent compound to provide a given color difference of the emission wavelength from a non-excited state to a steady-state excited condition.

In some embodiments, the host compound includes Ca₁₋ₓSrₓAlSiN₃, Ca₂Si₅N₈, Sr₂Si₅N₈, Ba₂Si₅N₈, BaSi₇N₁₀, BaYSi₄N₇, Y₅(SiO₄)₃N, Y₄Si₂O₇N₂, YSiO₂N, Y₂Si₃O₃N₄, Y₂Si₃-xAlxO₃+xN₄-x, Ca_{1.5}Si₉Al₃N₁₆, Y_{0.5}Si₉Al₃O_{1.5}N_{14.5}, CaSiN₂, Y₂Si₄N₆C, and/or Y₆Si₁₁N₂₀O. Some embodiments provide that the activator material includes at least one of Ce, Eu, Sm, Yb, Gd and/or Tb. In some embodiments, the host compound material comprises YAG and the activator material comprises Cerium.

Some embodiments provide that the quantity of the activator material that is combined with the host compound material is less than about 2 mole percent to limit the conversion efficiency of the luminescent compound, to provide a given color shift of the emission wavelength from a non-excited state to a steady-state excited condition.

In some embodiments, the given color shift is determined using a given quantity of closed regions that each encompasses points that are visually indistinguishable from a center point of the closed region in two-dimensional color space. Some embodiments provide that the two-dimensional color space includes a 1931 CIE Chromaticity Diagram and the closed regions each include a MacAdam ellipse. In some embodiments, the given quantity of MacAdam ellipses is ten. Some embodiments provide that the given quantity of MacAdam ellipses is seven. In some embodiments, the given quantity of MacAdam ellipses is four.

Some embodiments provide that the quantity of activator material includes a thermal emission maximum quantity that is determined to limit a self-heating temperature change of the particle from a non-excited state to a steady-state excited condition.

In some embodiments, the activator material is combined with the host compound material in a quantity that limits a conversion efficiency of the luminescent compound to provide a given color difference of the emission wavelength from a non-excited state to a steady-state excited condition combined with an emission of a light emitting source that emits the received light Some embodiments of the present invention include operations corresponding to methods and/or systems for providing luminescent particles as described herein. Such operations may include estimating a target temperature range corresponding to a temperature change of a luminescent particle that is attributable to thermal energy that is generated by a down-conversion of a portion of received light having a first dominant wavelength to emitting light having a second dominant wavelength that is different from the first dominant wavelength. Operations may include estimating an upper limit of a quantity of activator material that is combined with a host compound material that corresponds to the target temperature range.

In some embodiments, estimating the target temperature range includes estimating the target temperature range using an estimated color shift that corresponds to the temperature change of the luminescent particle that is attributable to thermal energy that is generated by the down-conversion of the portion of received light.

Some embodiments provide that the upper limit of the quantity of activator material is less than about two mole percent. In some embodiments, the upper limit of the quantity of activator material corresponds to a reduced conversion efficiency that is less than a peak conversion efficiency that occurs with a greater quantity of activator material.

Some embodiments further include estimating a density of the luminescent particles relative to a specific light emitter to generate light at a given color point as a function of the upper limit of the quantity of activator material.

Some embodiments of the present invention include a light emitting device that includes a light emitting source that is configured to emit light having a first dominant wavelength and multiple luminescent particles. Some embodiments provide that the luminescent particles include a luminescent compound that is configured to absorb a portion of light emitted from the light emitting source and to emit light having a second dominant wavelength that is different from the first dominant wavelength. In some embodiments, the luminescent compound includes a host compound material and an activator material that is combined with the host compound material. The activator material may be provided in a quantity that limits a conversion efficiency of the luminescent compound to provide a given color shift of the emission wavelength from a non-excited state to a steady-state excited condition. Some embodiments include a silicone encapsulant in which the luminescent particles are dispersed.

In some embodiments, an upper limit of the quantity of activator material corresponds to a reduced conversion efficiency that is less than a peak conversion efficiency that occurs with a greater quantity of activator material. Some embodiments provide that the luminescent particles are dispersed within the silicone encapsulant in a first density that corresponds to the reduced conversion efficiency. The first density may be greater than a second density that corresponds to the luminescent compound with a greater quantity of activator material than the upper limit.

In some embodiments, the host compound includes Ca₁₋ₓSrₓAlSiN₃, Ca₂Si₅N₈, Sr₂Si₅N₈, Ba₂Si₅N₈, BaSi₇N₁₀, BaYSi₄N₇, Y₅(SiO₄)₃N, Y₄Si₂O₇N₂, YSiO₂N, Y₂Si₃O₃N₄, Y₂Si₃-xAlxO₃+xN₄-x, Ca_{1.5}Si₉Al₃N₁₆, Y_{0.5}Si₉Al₃O_{1.5}N_{14.5}, CaSiN₂, Y₂Si₄N₆C, and/or Y₆Si₁₁N₂₀O. Some embodiments provide that the activator material includes at least one of Ce, Eu, Sm, Yb, Gd and/or Tb.

In some embodiments, the quantity of the activator material that is combined with the host compound material is less than about 2 mole percent to limit the conversion efficiency of the luminescent compound. Some embodiments provide that limiting the conversion efficiency may provide a given color shift of the emission wavelength from a non-excited state to a steady-state excited condition.

Some embodiments provide that an emission color of the light emitting device is a combination of the first dominant wavelength and the second dominant wavelength.

Some embodiments include a light emitting device that includes a plurality of luminescent particles including a luminescent compound that, when placed in a path of light having a first dominant wavelength, is configured to absorb a portion of the light emitted from the light emitting source and to emit light having a second dominant wavelength that is different from the first dominant wavelength. Some embodiments provide that the luminescent compound includes a host compound material and an activator material that is combined with the host compound material in a quantity that limits a conversion efficiency of the luminescent compound to provide a given color difference of the emission wavelength from a non-excited state to a steady-state excited condition.

In some embodiments, the host compound material includes a yttrium aluminum garnet phosphor (YAG) and the activator material includes Cerium. Some embodiments provide that the activator material includes less than about 2 mole percent Cerium.

Some embodiments provide that the luminescent compound includes a red nitride phosphor and the activator material comprises less than about 0.2 mole percent Eu. In some embodiments, the red nitride phosphor includes Ca_{1-x-y}SrₓEu_{y}AlSiN₃ where y includes a value that is less than about 0.002. Some embodiments provide that the red nitride phosphor includes Ca_{1-x-y}SrₓEu_{y}AlSiN₃ where y includes a value that is less than about 0.0015.

In some embodiments, the luminescent compound includes a BOSE type green-emitting phosphor and the activator material includes less than about 0.2 mole percent.

Some embodiments provide that the luminescent compound includes a green-emitting phosphor including (Y₁₋ₓLuₓ)₃(Al_{1-y}Ga_{y})₅O₁₂:Ce where x and y include values in a range from about 0 to about 1.

In some embodiments, the host compound material includes a (Tb₁₋ₓREₓ)₃Al₅O₁₂:Ce phosphor (TAG) and the activator material includes less than about 0.2 mole percent Cerium.

Some embodiments provide that the quantity of the activator material that is combined with the host compound material is less than about 2 mole percent to limit the conversion efficiency of the luminescent compound, to provide a given color shift of the emission wavelength from a non-excited state to a steady-state excited condition.

In some embodiments, a first portion of the luminescent particles is configured to emit light corresponding to the second dominant wavelength and a second portion of the luminescent particles is configured to emit light having a third dominant wavelength that is different from the second dominant wavelength.

### BRIEF DESCRIPTION OF THE DRAWINGS

FIG. 1 is a schematic diagram of a luminescent particle according to some embodiments of the present invention.

FIG. 2 is a graph illustrating individual and combined luminous intensities of an emitter and luminescent particles at an initial state and a steady state temperature according to some embodiments of the present invention.

FIG. 3 is a graph of a two-dimensional color space illustrating the shift in color as the temperature of the luminescent particle changes according to some embodiments of the present invention.

FIG. 4 is a graph illustrating color shift versus temperature of emitters with different types of luminescent particles according to some embodiments of the present invention.

FIG. 5 is a graph illustrating efficacy ratios of an emitter and emitters with different types of luminescent particles according to some embodiments of the present invention.

FIG. 6 is a graph illustrating efficiency ratios of an emitter and emitters with different types of luminescent particles according to some embodiments of the present invention.

FIGS. 7A-C are graphs each illustrating efficiency ratios versus current of an emitter and a type of luminescent particles at three different respective operating temperatures according to some embodiments of the present invention.

FIGS. 8A and 8B are graphs illustrating relational properties of luminescent particles according to some embodiments of the present invention.

FIG. 9 is a graph illustrating how the upper limit of a quantity of an activator material in a luminescent particle may be determined as a function of a target range of color shift that occurs from particle self-heating according to some embodiments of the present invention.

FIGS. 10A and 10B are schematic side cross-sectional views of exemplary light emitting devices that include luminescent particles according to some embodiments of the present invention.

FIG. 11 a flow diagram illustrating methods of providing a luminescent particle according to some embodiments of the present invention.

### DETAILED DESCRIPTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers refer to like elements throughout the specification.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. Accordingly, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

According to some embodiments of the present invention, luminescent particles provided may include luminescent nitride particles and may be useful as phosphors. The term “luminescent particle” is used herein to describe phosphor particles made from host materials including oxides, nitrides, oxynitrides, sulfides, selenides, halides and/or silicates of zinc, cadmium, manganese, aluminum, silicon, and/or various rare earth metals. For example, phosphors may include Ce-doped YAG (YAG:Ce³⁺, or Y₃Al₅O₁₂:Ce³⁺), Ba, Ca, Sr orthosilicate, and/or TAG:Ce among others. The term “luminescent nitride particle” is used herein to describe particles including phosphors for which the anion is predominantly nitride and in which the amount of oxygen present in the crystal structure is so minimal as to avoid changing the crystal structure from that fundamentally formed by the nitride.

The luminescent particles may include a host compound material and an activator material that is combined with the host compound material in a determined quantity. Stated differently the host compound may be doped with the activator material. Some embodiments provide that the host compound includes Ca₁₋ₓSrₓAlSiN₃, Ca₂Si₅N₈, Sr₂Si₅N₈, Ba₂Si₅N₈, BaSi₇N₁₀, BaYSi₄N₇, Y₅(SiO₄)₃N, Y₄Si₂O₇N₂, YSiO₂N, Y₂Si₃O₃N₄, Y₂Si₃-xAlxO₃+xN₄-x, Ca_{1.5}Si₉Al₃N₁₆, Y_{0.5}Si₉Al₃O_{1.5}N_{14.5}, CaSiN₂, Y₂Si₄N₆C, and/or Y₆Si₁₁N₂₀O, among others. In some embodiments, the activator material includes at least one of Ce, Eu, Sm, Yb, Gd and/or Tb, among others.

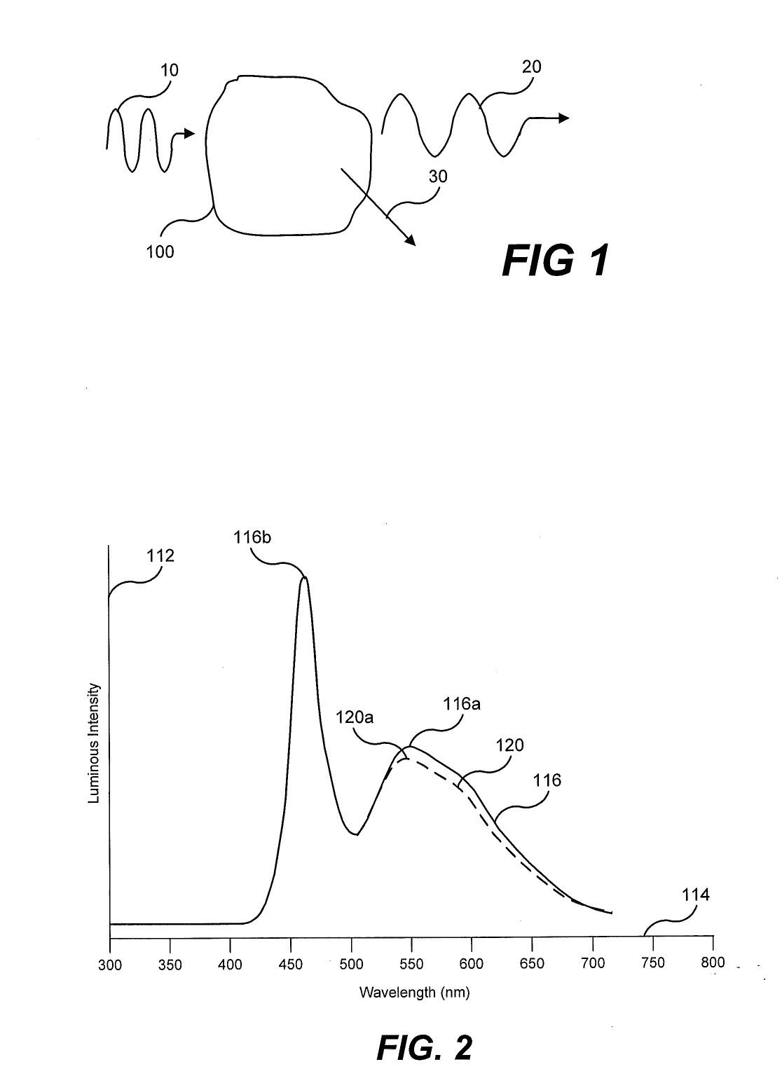

Reference is now made to FIG. 1, which is a schematic diagram of a luminescent particle according to some embodiments of the present invention. A luminescent particle 100 may receive light 10 that is emitted from an emitter (not shown here). A portion of the received light 10 may be absorbed by the luminescent particle 100, which may be referred to as excitation. As a result of the excitations, the luminescent particle 100 may generate emitted light 20, which may be referred to as emission. Generally the received light 10 may include dominant wavelength that is short relative to a dominant wavelength of the emitted light 20. For example, in some embodiments, the received light 10 be include a dominant wavelength corresponding to a blue color and the emitted light 20 may include a dominant wavelength corresponding to a green, yellow or red color.

In addition to the emitted light 20, consistent with the law of conservation of energy, the luminescent particle 100 may also produce phonons which are realized as heat energy 30. In this regard, excitation of a luminescent particle 100 may result in a self-heating of the luminescent particle 100. For example, the heat energy 30 may be about twenty percent of the emission energy, depending on the wavelengths of the excitation and emission.

In use and operation, the luminescent particle 100 may be contained within a media and/or encapsulant such as, for example, silicone, among others. Although some of the heat energy 30 may be conducted away from the luminescent particle 100 via the media and/or encapsulant, such conduction may be limited by the heat transfer properties of the media and/or encapsulant. In this regard, the temperature of the luminescent particle 100 may increase due to self-heating without means for significant heat dissipation. As the temperature of the luminescent particle 100 increases, the intensity of the emitted light decreases. Specifically, as the luminescent particle heats up, the non-radiative pathways therein may become more energetically favorable, which has the effect of decreasing the visible emissions. This phenomenon may be referred to as thermal quenching.

One aspect of a heat related color shift in the combined light of an LED and the luminescent particle may result from a change in the wavelength of light emitted from the luminescent particle 100. A more dominant source of a heat related color shift in the combined light of an LED and the luminescent particle may be a change in the intensity ratio between the dominant wavelength emitted from the LED and the dominant wavelength of the light emitted from the luminescent particle. For example, as the temperature of the luminescent particle 100 increases, the portion of the combined light that is attributable to the luminescent particle 100 decreases by virtue of the decrease in emissions from the luminescent particle 100 corresponding to thermal quenching. As the intensity of the light emitted from the luminescent particle 100 decreases relative to the intensity of the light emitted from the LED, the color of the combined light may shift towards that of the light emitted from the LED as a result of the self-heating of the luminescent particle 100.

For example, reference is now made to FIG. 2, which is a graph illustrating spectral distributions of emitters and luminescent particles at an initial and a steady state temperature according to some embodiments of the present invention. The graph includes a vertical axis 112 corresponding to luminous intensity and a horizontal axis 114 corresponding to wavelength in nanometers (nm). The initial temperature curve 116 includes the emission spectra 116b of the emitter and emission 116a of the luminescent particles at an initial temperature value. A steady state temperature curve 120 includes the emission spectra 120a corresponding to the luminescent particles at a steady state operating temperature and substantially the same emission spectra 116b of the emitter as at the initial temperature. Note that the luminous intensity of the emitter does not change substantially from the initial temperature to the steady state temperature. In contrast, the luminous intensity of the spectral emission of the luminescent particles decreases at the steady state relative to the initial temperature. In this regard, as the temperature of the luminescent particles increases the color of the spectral emission thereof shifts.

Some embodiments provide that the conversion efficiency may be limited by using a quantity of activator material that is less than about 2 mole percent of the luminescent compound. In this manner, a given color shift of the emission wavelength from a non-excited state to a steady-state excited condition may be achieved. The given color shift is determined using a given quantity of closed regions that each encompasses points that are visually indistinguishable from a center point of the closed region in two-dimensional color space. In some embodiments, such regions may include MacAdam ellipse and the two-dimensional color space includes a 1931 CIE Chromaticity Diagram. Some embodiments provide that the given quantity of MacAdam ellipses is ten, however, some embodiments may use other quantities of MacAdam ellipses including, for example, one, four and/or seven, among others.

In some embodiments, the quantity of activator material may include a thermal emission maximum quantity that operates to limit a self-heating temperature change of the particle from a non-excited state to a steady-state excited condition. In this manner, color uniformity of the emitted light 20 from the luminescent particle that is a function of particle self-heating may be improved. Further, the color uniformity of the combined light from the LED and the luminescent particle may be improved.

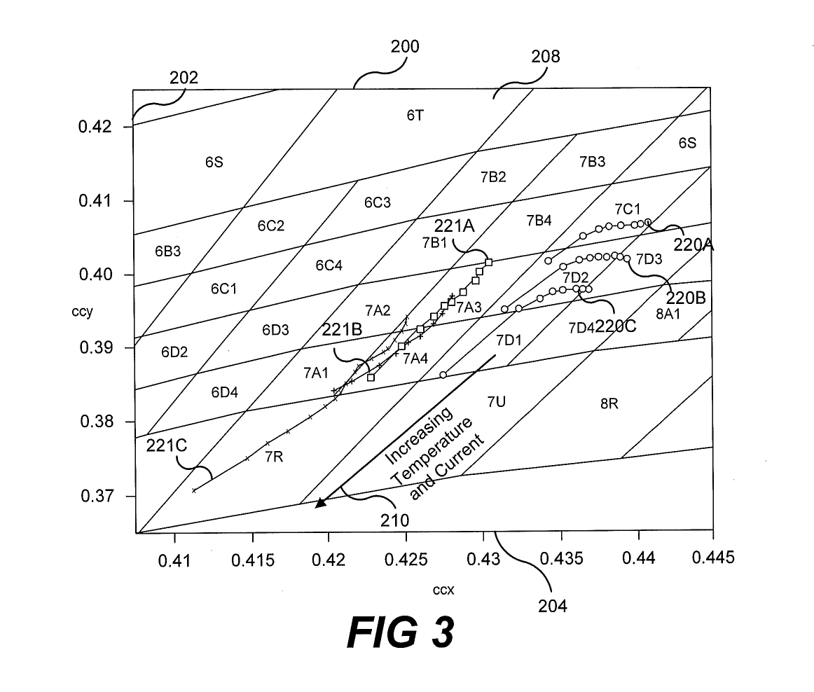

Reference is now made to FIG. 3, is a graph of a two-dimensional color space illustrating the shift in color corresponding to several luminescent particles at different temperatures and currents according to some embodiments of the present invention. The graph 200 includes two dimensional color space having a ccx axis 204 and a ccy axis 202 such that a point on the graph 200 that corresponds to a pair of ccx, ccy coordinates corresponds to a specific color. The color space is divided into regions, which may also be referred to as bins 208. The bins 208 represent a combined color of the light emitted from an LED and the emitted light from luminescent particles that are excited by the light from the LED. Each bin 208 may define a different region in the color space that corresponds to a predefined level of perceived change to the human eye. In this regard, all of the colors defined by coordinate pairs in each bin 208 may be perceived as substantially the same color.

Plots 220A-C represent color coordinates of the light emitted from an LED with BOSE phosphor particles as the current through the LED is increased at three different temperatures. Plot 220A represents the represent color coordinates of the light emitted from the LED with BOSE phosphor particles as the current through the LED while the temperature is 20 degrees C. Note that as the current increases, the color of the combined light of the emitter/BOSE phosphor at 20 degrees C. shifts towards the lower left direction of the two-dimensional color space.

Similarly, plot 220B represents the represent color coordinates of the light emitted from the LED with BOSE phosphor particles as the current through the LED while the temperature is 60 degrees C. Note that as the current increases, the color of the combined light of the emitter/BOSE phosphor at 60 degrees C. shifts towards the lower left direction of the two-dimensional color space. Also note that the increased temperature from 20 degrees C. to 60 degrees C. results in the corresponding points on the plot being shifted towards the lower left.

Similarly, plot 220C represents the represent color coordinates of the light emitted from the LED with BOSE phosphor particles as the current through the LED while the temperature is 95 degrees C. Note that as the current increases, the color of the combined light of the emitter/BOSE phosphor at 95 degrees C. shifts towards the lower left direction of the two-dimensional color space. Also note that the increased temperature to 95 degrees C. results in the corresponding points on the plot 220C being shifted even further towards the lower left relative to the lower temperature plots 220A-B.

Plots 221A-C represent color coordinates of the light emitted from an LED with lutetium aluminum garnet (LuAG) phosphor particles as the current through the LED is increased at three different temperatures. Plot 221A represents the represent color coordinates of the light emitted from the LED with LuAG phosphor particles as the current through the LED while the temperature is 20 degrees C. Note that as the current increases, the color of the combined light of the emitter/LuAG at 20 degrees C. shifts towards the lower left direction of the two-dimensional color space.

Similarly, plot 221B represents the represent color coordinates of the light emitted from the LED with LuAG phosphor particles as the current through the LED while the temperature is 60 degrees C. Note that as the current increases, the color of the combined light of the emitter/LuAG phosphor at 60 degrees C. shifts towards the lower left direction of the two-dimensional color space. Also note that the increased temperature from 20 degrees C. to 60 degrees C. results in the corresponding points on the plot being shifted towards the lower left.

Similarly, plot 221 represents the represent color coordinates of the light emitted from the LED LuAG phosphor particles as the current through the LED while the temperature is 95 degrees C. Note that as the current increases, the color of the combined light of the emitter/LuAG phosphor at 95 degrees C. shifts towards the lower left direction of the two-dimensional color space. Also note that the increased temperature to 95 degrees C. results in the corresponding points on the plot 221C being shifted even further towards the lower left relative to the lower temperature plots 221A-B.

As illustrated by the arrow 210, the color shifts towards the lower left direction of the two-dimensional color space as the temperature and current increase. As color uniformity may be a beneficial characteristic of a light emitting device, reducing the self-heating of the luminescent particle 100 may result in a reduced shift in the color therefrom.

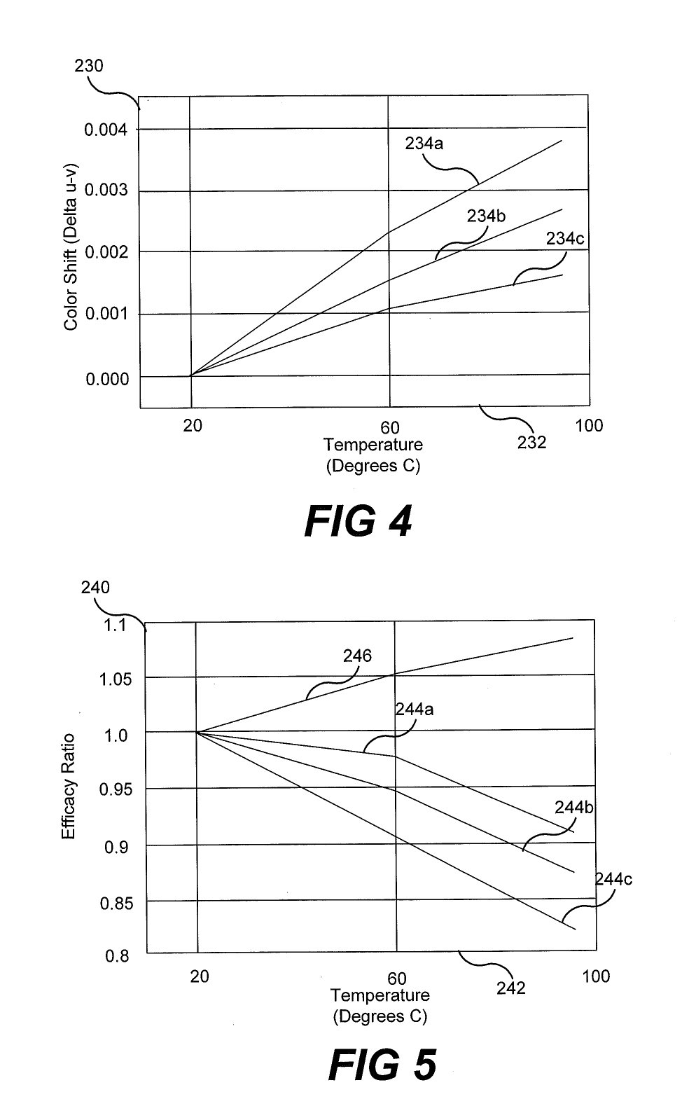

Reference is now made to FIG. 4, which is a graph illustrating color shift versus temperature of emitters with different types of luminescent particles according to some embodiments of the present invention. The graph includes a vertical axis 230 corresponding to the color shift of the combined emission of an emitter and luminescent particles expressed in terms of delta u-v coordinates, which are used to define a point in the chromaticity space that became the CIE 1976 color space. The operating temperature is defined along the horizontal axis 232 in degrees C. The shift in color versus temperature for an emitter/BOSE phosphor combined emission from 20 degrees C. to about 95 degrees C. is illustrated in plot 234A. As illustrated, the BOSE phosphor combination experiences nearly a four step (0.001=1 step) change in color over the measured temperature range. The shift in color versus temperature for an emitter with LuAG phosphor from 20 degrees C. to about 95 degrees C. is illustrated in plot 234B. As illustrated, the LuAG phosphor combination experiences greater than a two step change in color over the measured temperature range. The shift in color versus temperature for an emitter with yttrium aluminum garnet (YAG) phosphor from 20 degrees C. to about 95 degrees C. is illustrated in plot 234C. As illustrated, the YAG phosphor combination experiences nearly a two step change in color over the measured temperature range. Although the different phosphors (luminescent particles) include different response levels over the range of temperatures measured, each demonstrates a measurable change in color over the range of temperatures from 20 degrees C. to about 95 degrees C.

Reference is now made to FIG. 5, which is a graph illustrating efficacy ratios of an emitter without luminescent particles and emitters with different types of luminescent particles according to some embodiments of the present invention. The graph includes a vertical axis 240 corresponding to the efficacy ratio normalized relative to the initial conditions at 20 degrees C. The operating temperature is defined along the horizontal axis 242 in degrees C. Plot 246 illustrates the efficacy ratio of an emitter that is not supplemented by any luminescent particles. As illustrated, the efficacy of the emitter continues to increase as the temperature increases.

Plots 244A-C illustrate the efficacy ratios of emitters with different types of phosphors (luminescent particles). The efficacy ratio of an emitter/YAG phosphor combined emission is illustrated in plot 244A. As illustrated, the efficacy of the emitter/YAG phosphor combined emission drops as the temperature increases. Similarly, the efficacy ratio of an emitter/BOSE phosphor combined emission is illustrated in plot 244B. As illustrated, the efficacy of the emitter/BOSE phosphor combined emission drops as the temperature increases. Similarly, the efficacy ratio of an emitter/LuAG phosphor, as illustrated in plot 244C, decreases as the temperature increases. As evidenced by the divergent efficacy ratio plots of the emitter without a phosphor versus the emitter with the different phosphors, a reduction in efficacy may be attributed to the change in emission characteristics of the phosphors as the temperature increases.

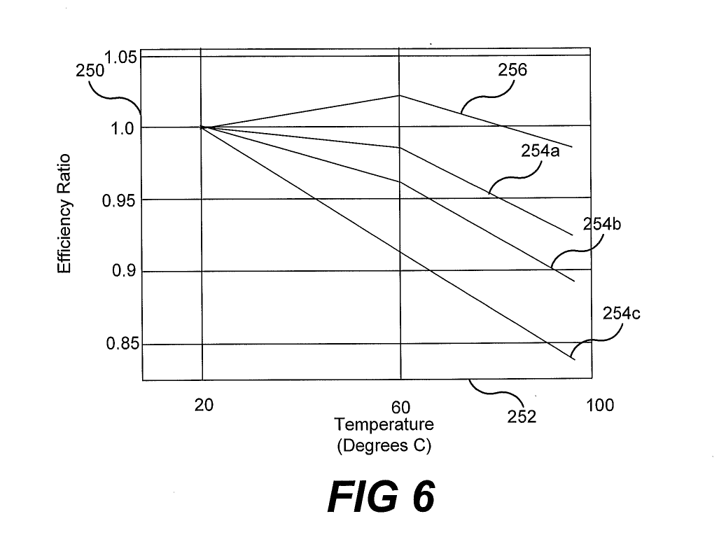

Reference is now made to FIG. 6, which is a graph illustrating efficiency ratios of an emitter and emitters with different types of luminescent particles according to some embodiments of the present invention. The graph includes a vertical axis 250 corresponding to the efficiency ratio normalized relative to the initial conditions at 20 degrees C. The operating temperature is defined along the horizontal axis 252 in degrees C. Plot 256 illustrates the efficiency ratio of an emitter that is not supplemented by any luminescent particles. As illustrated, the efficiency of the emitter is slightly higher at 60 degrees C. than at 20 degrees C., but then drops at higher temperatures.

Plots 254A-C illustrate the efficiency ratios of emitters with different types of phosphors (luminescent particles). The efficiency ratio of an emitter/YAG phosphor combined emission is illustrated in plot 254A. As illustrated, the efficiency of the emitter/YAG phosphor combined emission drops as the temperature increases. Similarly, the efficiency ratio of an emitter/BOSE phosphor combined emission is illustrated in plot 254B. As illustrated, the efficiency of the emitter/BOSE phosphor combined emission drops as the temperature increases. Similarly, the efficiency ratio of an emitter/LuAG phosphor, as illustrated in plot 254C, decreases as the temperature increases. As evidenced by the different efficiency ratio plots of the emitter without a phosphor versus the emitter with the different phosphors, a significant additional reduction in efficiency may be attributed to the change in emission characteristics of the phosphors as the temperature increases.

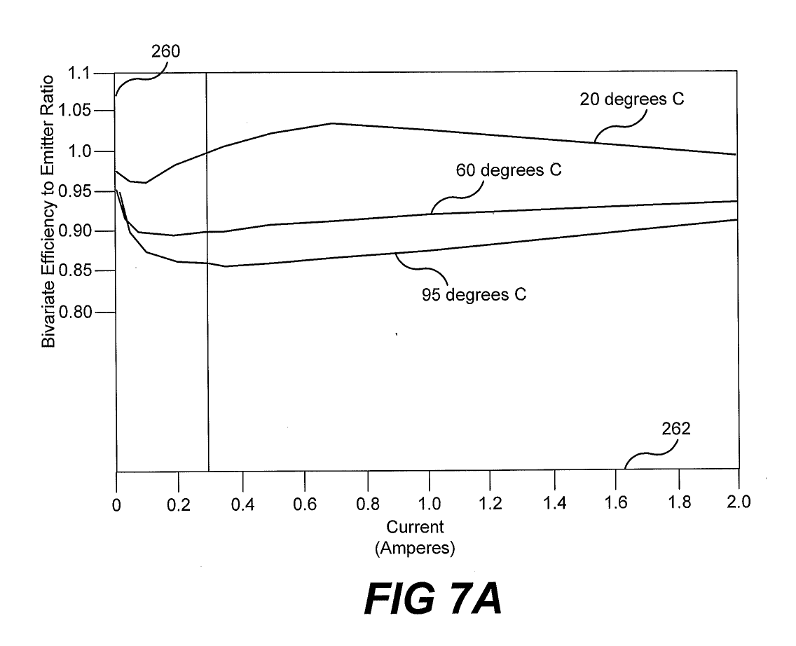

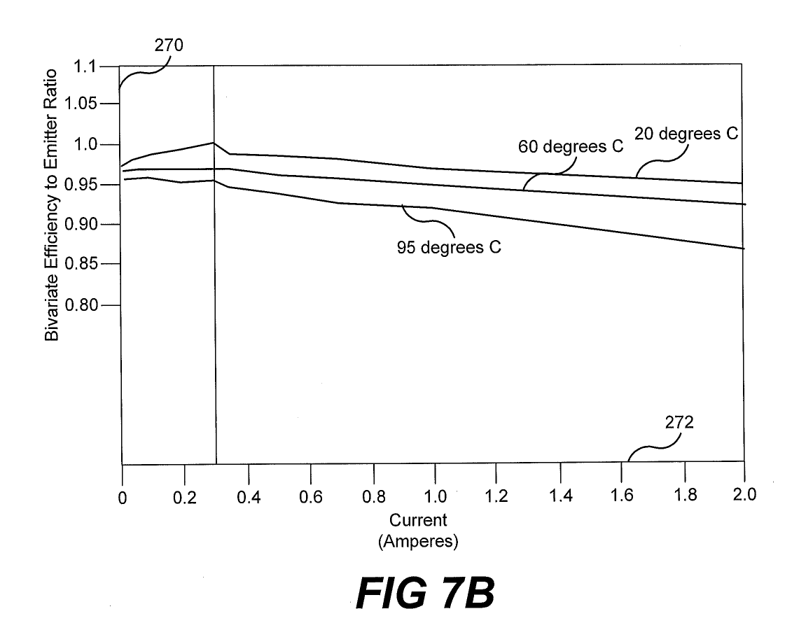

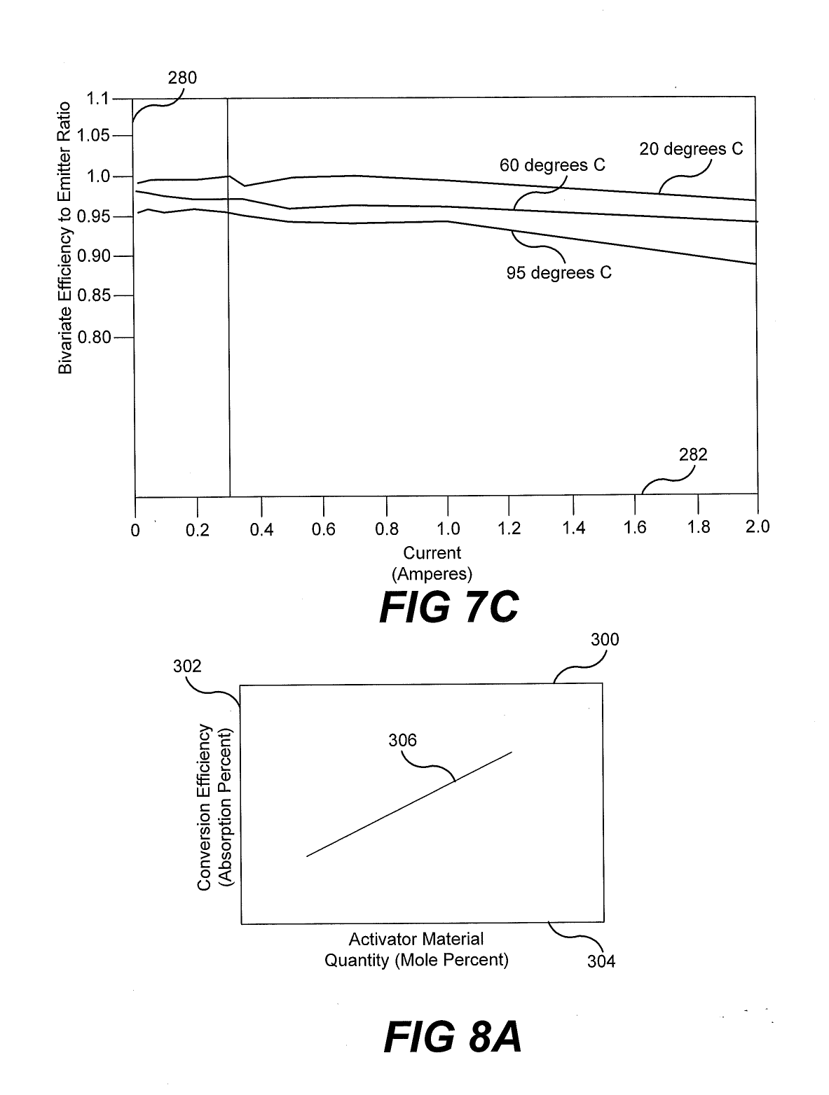

Reference is now made to FIGS. 7A-C, which are graphs each illustrating efficiency ratios versus current of an emitter and a type of luminescent particles at three different respective operating temperatures according to some embodiments of the present invention. The graph illustrated in FIG. 7A includes a vertical axis 260 that corresponds to the bivariate efficiency to emitter ratio as determined by dividing the efficiency ratio of the emitter/YAG phosphor by the emitter efficiency change with respect to temperature and current. The horizontal axis 262 designates the operating current in amperes. Each of the three plots is labeled with the corresponding one of the 20 degrees C., 60 degrees C. and 95 degrees C. designations. As illustrated, at each the three temperatures, the YAG phosphor provides a relatively flat efficiency ratio over the current range, especially starting at around 300 mA.

Similarly, the graph illustrated in FIG. 7B includes a vertical axis 270 that corresponds to the bivariate efficiency to emitter ratio as determined by dividing the efficiency ratio of the emitter/BOSE phosphor by the emitter efficiency change with respect to temperature and current. The horizontal axis 272 designates the operating current in amperes. Each of the three plots is labeled with the corresponding one of the 20 degrees C., 60 degrees C. and 95 degrees C. designations. As illustrated, at each the 20 degrees C. and the 60 degrees C. temperatures, the BOSE phosphor provides a relatively flat efficiency ratio over the current range, especially starting at around 300 mA. At the 90 degrees C. temperature, the BOSE phosphor exhibits a more pronounced decrease in efficiency ratio as the current increases.

Similarly, the graph illustrated in FIG. 7C includes a vertical axis 280 that corresponds to the bivariate efficiency to emitter ratio as determined by dividing the efficiency ratio of the emitter/LuAG phosphor by the emitter efficiency change with respect to temperature and current. The horizontal axis 282 designates the operating current in amperes. Each of the three plots is labeled with the corresponding one of the 20 degrees C., 60 degrees C. and 95 degrees C. designations. As illustrated, at each the 20 degrees C. and the 60 degrees C. temperatures, the LuAG phosphor provides a relatively flat efficiency ratio over the current range, especially starting at around 300 mA. At 90 degrees C., the LuAG phosphor exhibits a more pronounced decrease in efficiency ratio as the current increases, especially beyond about 1.0 amperes.

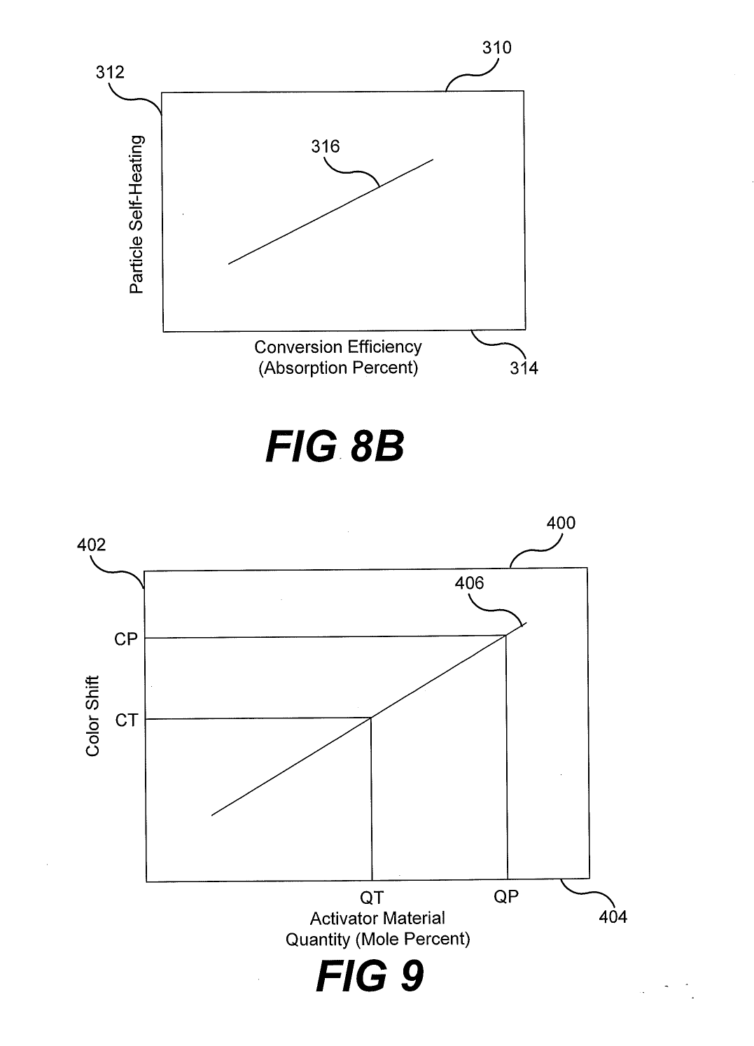

Reference is now made to FIGS. 8A and 8B, which are graphs illustrating properties of luminescent particles according to some embodiments of the present invention. FIG. 8A is a graph 300 that illustrates a general relationship between the conversion efficiency and the quantity of activator material that is used to dope the host compound. The horizontal axis 304 represents the quantity of activator material that is used to dope the host compound and may be expressed as mole percent of the luminescent compound. The vertical axis 302 represents the conversion efficiency of the luminescent particle 100 and may be expressed as the absorption percent. The absorption percent refers to the quantity of the light received by the luminescent particle 100 that is absorbed and converted into emitted light. As illustrated by the plot 306, as the quantity of the activator material increases, the conversion efficiency increases. Although the plot 306 is illustrated as indicating a linear correspondence between the activator material quantity and the conversion efficiency, such illustration is a generalization. Additionally, the plot 306 as illustrated does not address boundary conditions such as saturation points or regions that may occur at maximum practical levels of doping. In this regard, the illustrated correspondence between the quantity of activator material and the conversion efficiency is simplified and may represent a range of values over which the correspondence applies.

Reference is now made to FIG. 8B, which is a graph 310 that illustrates a general relationship between the particle self-heating and the conversion efficiency of the luminescent particle 100. The vertical axis 312 represents the self-heating characteristics of the luminescent particle. The horizontal axis 314 represents the conversion efficiency of the luminescent particle 100 and may be expressed as the absorption percent. As illustrated by the simplified plot 316, as the conversion efficiency (absorption percent) increases, the particle self-heating of the luminescent particle 100 from the excitation thereof increases. As many techniques may generally focus on increasing the efficiency to reduce the number of luminescent particles necessary for a given combined light color, it may be counter-intuitive to reduce the conversion efficiency. Although the plot 316 is illustrated as indicating a linear correspondence between the conversion efficiency and the particle self-heating, such illustration is a generalization. Additionally, the plot 316 as illustrated does not address boundary conditions such as saturation points or regions that may occur at maximum practical levels conversion efficiency. In this regard, the illustrated correspondence between the conversion efficiency and the particle self-heating is simplified and may represent a range of values over which the correspondence applies.

Accordingly, a positive correlation between the quantity of activator materials and particle self heating may be determined. As discussed above regarding FIG. 2, since the higher operating temperatures may result in a decrease in the luminous intensity of the luminescent particle, a reduction in the quantity of activator material may result in a reduction of the decrease in luminous intensity of the light emitted from the luminescent particle. Accordingly, the reduction in the quantity of activator material may result in a decreased shift in color from an initial temperature to a steady state temperature.

Reference is now made to FIG. 9, which is a graph illustrating how the upper limit of a quantity of an activator material in a luminescent particle may be determined as a function of a target range of color shift that occurs from particle self-heating according to some embodiments of the present invention. The vertical axis 402 represents the amount of shift in the color of combined light emitted from the emitter and luminescent particle. The horizontal axis 404 represents the quantity of activator material that is used to dope the host material in the luminescent compound of the luminescent particle 100. As illustrated by the simplified plot 406, the quantity of activator material may be positively correlated with the amount of change in the color that results from self-heating of the luminescent particle 100. Although the plot 406 is illustrated as indicating a linear correspondence between the quantity of activator material and the color shift in the light emitted from the luminescent particle 100, such illustration is a generalization provided for explanation of the concepts herein.

Some embodiments provide that a quantity of activator material QP that may correspond to peak conversion efficiency may also correspond to a peak color shift CP due to the decreased contribution of the light emitted from the luminescent particle. Since color uniformity emitted from the combined light of the emitter and luminescent particle 100 may improve performance, a target color shift CT may be determined to result in an acceptable level of color shift. Accordingly, a target quantity of activator material QT that corresponds to the target color shift CT may be determined. In this manner, the luminescent particle may include a host material with reduced doping of the activator material to improve color uniformity.

In some embodiments, the peak color shift CP and/or the target color shift CT may be expressed as quantities of MacAdam steps. For example, as illustrated in FIG. 4, each 0.001 increment of uv values may represent one MacAdam step. Accordingly, some embodiments may provide that the peak color shift CP may be determined as three, four or more steps. In this regard, the target color shift CT may be determined as a lower quantity of steps than peak color shift CP, such as two, three or four steps, among others. Additionally, some embodiments provide that the peak quantity of activator material QP may be 2.5 mole percent or greater. In some embodiments, to achieve the target color shift, the target quantity of activator material QT may be around 2.0 mole percent and/or lower.

In use and operation, an application that relies on a particular combination of light from an emitter and converted light emitted from luminescent particles 100 may use a particular quantity or density of luminescent particles 100 to achieve the desired combined color output. However, since the conversion efficiency of the luminescent particles 100 is reduced by virtue of the activator material quantity QT, then total emitted light from the same quantity of luminescent particles 100 is reduced. In this regard, to achieve the same amount of light from the luminescent particles 100, the quantity of particles is increased. Although each of the luminescent particles 100 may exhibit reduced self-heating, the increase in the quantity of luminescent particles 100 may increase the total heat energy generated by the luminescent particles collectively to a level of heat energy that may be consistent with the fewer more efficient luminescent particles that are doped at QP. Even though the total heat may be consistent regardless of the quantity of activator material, the increased number of luminescent particles 100 may result in an increase in surface area over which the heat may be dissipated. In this regard, the temperature increase of individual particles due to self-heating may be reduced thus reducing the decrease in the luminous intensity therefrom.

Additionally, by increasing the quantity of luminescent particles 100, light emitted therefrom may exhibit greater diffusion than with fewer luminescent particles 100. For example, light that originates and/or emanates from a greater number of points, surfaces and/or particles may be more diffuse than light from fewer points, surfaces and/or particles.

Further, by reducing the self-heating, the luminescent particle 100 may operate at lower temperatures, which may increase the functional lifetime of the luminescent particle 100. In this regard, lower temperatures of the luminescent particles 100 may reduce and/or delay degradation of the encapsulant in which the particle may be suspended.

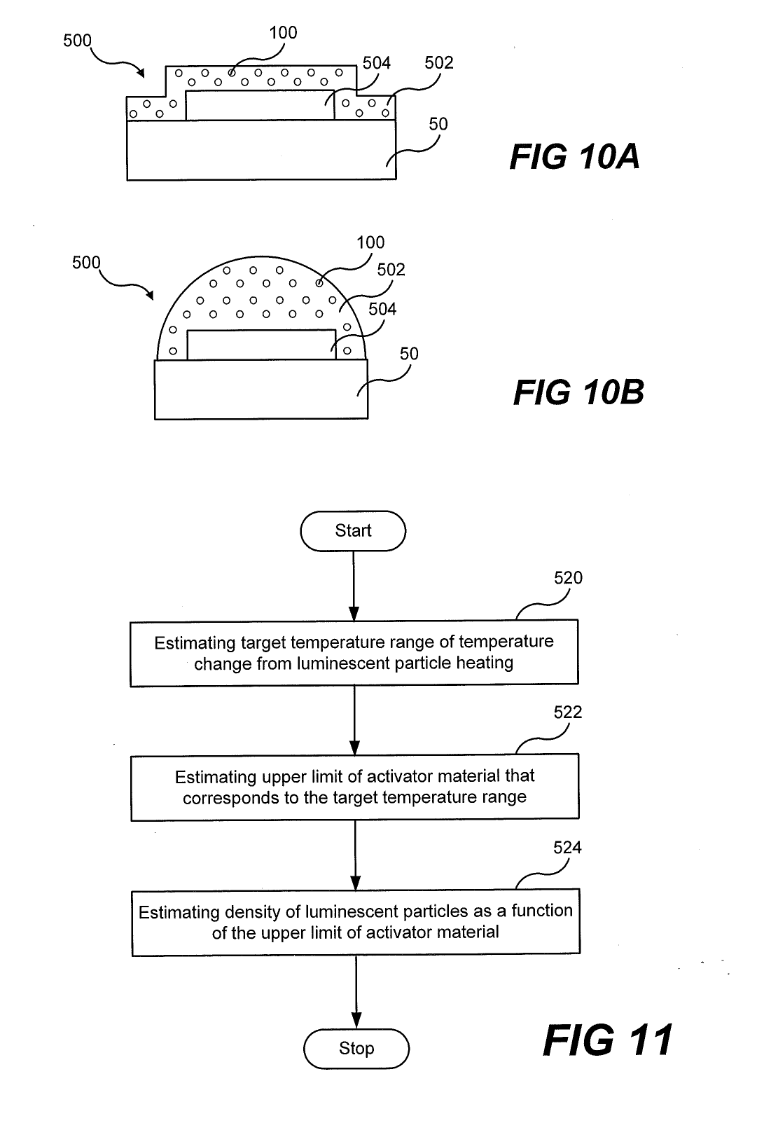

Reference is now made to FIGS. 10A and 10B, which are schematic side cross-sectional views of exemplary light emitting devices that include luminescent particles according to some embodiments of the present invention. A light emitting device 500 may include a light emitting source 504 that is configured to emit light therefrom. Some embodiments provide that the emitted light may include light having a first dominant wavelength, such as, for example, a wavelength corresponding to a blue light.

The light emitting source may include a light emitting diode, a laser diode and/or other semiconductor device that includes one or more semiconductor layers, which may include silicon, silicon carbide, gallium nitride and/or other semiconductor materials, a substrate which may include sapphire, silicon, silicon carbide and/or other microelectronic substrates, and one or more contact layers, which may include metal and/or other conductive layers. The design and fabrication of semiconductor light emitting devices are well known to those having skill in the art and need not be described in detail herein.

For example, light emitting devices according to some embodiments of the present invention may include structures such as the gallium nitride-based LED and/or laser structures fabricated on a silicon carbide substrate, such as those devices manufactured and sold by Cree, Inc. of Durham, N.C. The present invention may be suitable for use with LED and/or laser structures that provide active regions such as described in U.S. Pat. Nos. 6,201,262; 6,187,606; 6,120,600; 5,912,477; 5,739,554; 5,631,190; 5,604,135; 5,523,589; 5,416,342; 5,393,993; 5,338,944; 5,210,051; 5,027,168; 5,027,168; 4,966,862 and/or 4,918,497, the disclosures of which are incorporated herein by reference in their entirety as if set forth fully herein. Other suitable LED and/or laser structures are described in published U.S. Patent Application Publication No. US 2003/0006418 A1 entitled Group III Nitride Based Light Emitting Diode Structures With a Quantum Well and Superlattice, Group III Nitride Based Quantum Well Structures and Group III Nitride Based Superlattice Structures, published Jan. 9, 2003, as well as published U.S. Patent Application Publication No. US 2002/0123164 A1 entitled Light Emitting Diodes Including Modifications for Light Extraction and Manufacturing Methods Therefor, the disclosures of which are hereby incorporated herein by reference in their entirety as if set forth fully herein. Furthermore, phosphor coated LEDs, such as those described in U.S. application Ser. No. 10/659,241, entitled Phosphor-Coated Light Emitting Diodes Including Tapered Sidewalls and Fabrication Methods Therefor, filed Sep. 9, 2003, the disclosure of which is incorporated by reference herein as if set forth fully, may also be suitable for use in some embodiments of the present invention. The LEDs and/or lasers may be configured to operate such that light emission occurs through the substrate. In such embodiments, the substrate may be patterned so as to enhance light output of the devices as is described, for example, in the above-cited U.S. Patent Application Publication No. US 2002/0123164 A1. Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

Multiple luminescent particles 100 include a luminescent compound that is configured to absorb a portion of the light emitted from the light emitting source and to emit light having a second dominant wavelength that is different from the first dominant wavelength. For example, some embodiments provide that the second dominant wavelength corresponds to a yellow color. In this regard, the yellow color light emitted from the luminescent particle 100 combined with the blue light from the light emitting source 504 may appear as white light.

As discussed above, some embodiments of the luminescent particle 100 include a phosphor that may be configured to down-convert received photons in the blue and/or ultraviolet portions of the visible spectrum into photons in longer wavelength portions of the visible spectrum. In some embodiments, a luminescent particle 100 may include a red nitride that is a phosphor composition that absorbs in the blue portion of the visible spectrum and emits in the red portion of the visible spectrum. Some embodiments provide that red emitting luminescent particles 100 may be combined with yellow emitting luminescent particles 100. The light emitted from the yellow emitting luminescent particles 100 and red emitting luminescent particles 100 may combine with blue light to produce a warm white light. As is known, varying the amount of red emitting luminescent particles 100 may vary the warmth of the white light. In this regard, a yellow to red weight percent ratio may be determined to yield a particular color point, as may be defined in a mathematically defined color space. For example, in some embodiments, the warm white light may correspond to CIE 1931 E7 or E8 bins, among others.

The luminescent compound may include a host compound material including, for example, any of Ca₁₋ₓSrₓAlSiN₃, Ca₂Si₅N₈, Sr₂Si₅N₈, Ba₂Si₅N₈, BaSi₇N₁₀, BaYSi₄N₇, Y₅(SiO₄)₃N, Y₄Si₂O₇N₂, YSiO₂N, Y₂Si₃O₃N₄, Y₂Si₃-xAlxO₃+xN₄-x, Ca_{1.5}Si₉Al₃N₁₆, Y_{0.5}Si₉Al₃O_{1.5}N_{14.5}, CaSiN₂, Y₂Si₄N₆C, and/or Y₆Si₁₁N₂₀O, among others. The luminescent compound may further include an activator material that is combined with the host compound material. The activator material may include, for example, any of Ce, Eu, Sm, Yb, Gd and/or Tb, among others.

Some embodiments provide that the activator material may be provided in a quantity that limits a conversion efficiency of the luminescent compound. In such embodiments, limiting the quantity of the activator material to limit the conversion efficiency may reduce the self-heating of the luminescent particle 100. Accordingly, a thermally related decrease in the luminous intensity of the light emitted from luminescent particle 100 may be reduced. As such, a color shift of the combined emission wavelength from a non-excited state to a steady-state excited condition may be reduced and/or regulated. For example, in some embodiments, an upper limit of the quantity of activator material corresponds to a reduced conversion efficiency that is less than a peak conversion efficiency that occurs with a greater quantity of activator material. In some embodiments, the quantity of the activator material that is combined with the host compound material is less than about 2 mole percent to limit the conversion efficiency of the luminescent compound, to provide a given color shift of the emission wavelength from a non-excited state to a steady-state excited condition.

The light emitting device may further include an encapsulant 502 that may provide support for the luminescent particles 100. For example, the luminescent particles 100 may be dispersed and/or suspended in a silicone encapsulant 502. Note that, as illustrated in FIG. 5A, the encapsulant 502 that includes the luminescent particles 100 may conformally coat the light emitting source 504 and/or a structure 50 on which the light emitting source 504 may be positioned. Some embodiments provide that the encapsulant 502 that includes the luminescent particles 100 is deposited on the light emitting source 504 as a drop, droplet, glob and/or miniglob that may or may not contact a structure 50 on which the light emitting source 504 is positioned.

Since the conversion efficiency of the luminescent particles 100 is reduced by virtue of the lower quantity of activator material, the luminescent particles may emit less light in the second wavelength than a comparable luminescent particle having a greater conversion efficiency. In this regard, the luminescent particles 100 may be dispersed within the silicone encapsulant 502 in a quantity and/or density that corresponds to the reduced conversion efficiency.

Reference is now made to FIG. 11, which is a flow diagram illustrating operations for providing a luminescent particle according to some embodiments of the present invention. Operations may include estimating a target temperature range corresponding to a temperature change of a luminescent particle that is attributable to thermal energy that is generated by a down-conversion of a portion of received light (block 520). Some embodiments provide that the received light includes a first dominant wavelength and that the luminescent particle down-converts the portion of received light into light having a second dominant wavelength that is different from the first dominant wavelength. The target temperature may be estimated using an estimated color shift that corresponds to the portion of the temperature change of the luminescent particle that is attributable to thermal energy that is generated by the down-conversion of the portion of received light.

Operations may further include estimating an upper limit of a quantity of activator material that is combined with a host compound material (block 522). In some embodiments, the quantity of activator material may correspond to the target temperature range. Some embodiments provide that the upper limit of the quantity of activator material is less than about two mole percent. In some embodiments, the upper limit of the quantity of activator material corresponds to a reduced conversion efficiency that is less than a peak conversion efficiency that occurs with a greater quantity of activator material. In this manner, the self-heating of the luminescent particle may be reduced to a level below that of a peak conversion efficiency and thus the reduction in luminous intensity of the luminescent particle that is associated with the self-heating may be reduced.

Some embodiments provide that operations may also include estimating a density and/or quantity of the luminescent particles relative to a specific light emitter as a function of the upper limit of the quantity of activator material (block 524). In this manner, light may be generated at a given color point as a function of the upper limit of the quantity of activator material. Additionally, the color shift of the combined light generated by the emitter and luminescent particles may be reduced.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A luminescent particle, comprising:
a luminescent compound that is configured to absorb a portion of received light and to emit light at an emission wavelength that is different from a wavelength of the portion of received light, the luminescent compound comprising:
a host compound material; and
an activator material that is combined with the host compound material in a quantity that limits a conversion efficiency of the luminescent compound to provide a given color difference of the emission wavelength from a non-excited state to a steady-state excited condition.

2. The particle according to claim 1, wherein the host compound includes Ca₁₋ₓSrₓAlSiN₃, Ca₂Si₅N₈, Sr₂Si₅N₈, Ba₂Si₅N₈, BaSi₇N₁₀, BaYSi₄N₇, Y₅(SiO₄)₃N, Y₄Si₂O₇N₂, YSiO₂N, Y₂Si₃O₃N₄, Y₂Si₃-xAlxO₃+xN₄-x, Ca_{1.5}Si₉Al₃N₁₆, Y_{0.5}Si₉Al₃O_{1.5}N_{14.5}, CaSiN₂, Y₂Si₄N₆C, and/or Y₆Si₁₁N₂₀O.

3. The particle according to claim 1, wherein the activator material includes at least one of Ce, Eu, Sm, Yb, Gd and/or Tb.

4. The particle according to claim 1, wherein the host compound material comprises a yttrium aluminum garnet phosphor (YAG) and the activator material comprises Cerium.

6. The particle according to claim 1, wherein the host compound material comprises a yttrium aluminum garnet phosphor (YAG) and the activator material comprises less than about 2 mole percent Cerium.

7. The particle according to claim 1, wherein the host compound material comprises a yttrium aluminum garnet phosphor (YAG) and the activator material comprises less than about 1.5 mole percent Cerium.

8. The particle according to claim 1, wherein the luminescent compound comprises a red nitride phosphor, and wherein the activator material comprises less than about 0.2 mole percent Eu.

9. The particle according to claim 8, wherein the red nitride phosphor includes Ca_{1-x-y}SrₓEu_{y}AlSiN₃ where y includes a value that is less than about 0.002.

10. The particle according to claim 8, wherein the red nitride phosphor includes Ca_{1-x-y}SrₓEu_{y}AlSiN₃ where y includes a value that is less than about 0.0015.

11. The particle according to claim 1, wherein the luminescent compound comprises a BOSE type phosphor and wherein the activator material comprises less than about 0.2 mole percent.

12. The particle according to claim 1, wherein the luminescent compound comprises a green-emitting phosphor including (Y₁₋ₓLuₓ)₃(Al_{1-y}Ga_{y})₅O₁₂:Ce where x and y include values in a range from about 0 to about 1.

13. The particle according to claim 1, wherein the host compound material comprises a Tb₃₋ₓREₓO_{y} phosphor (TAG) and wherein the activator material includes less than about 0.2 mole percent Cerium.

14. The particle according to claim 1, wherein the host compound material comprises a (Tb₁₋ₓREₓ)₃Al₅O₁₂:Ce phosphor (TAG) and wherein the activator material includes less than about 0.15 mole percent Cerium.

15. The particle according to claim 1, wherein the quantity of the activator material that is combined with the host compound material is less than about 2 mole percent to limit the conversion efficiency of the luminescent compound, to provide a given color shift of the emission wavelength from a non-excited state to a steady-state excited condition.

16. The particle according to claim 1, wherein the given color shift is determined using a given quantity of closed regions that each encompasses points that are visually indistinguishable from a center point of the closed region in two-dimensional color space.

17. The particle according to claim 16, wherein the two-dimensional color space includes a 1931 CIE Chromaticity Diagram and wherein the closed regions each include a MacAdam ellipse.

18. The particle according to claim 17, wherein the given quantity of MacAdam ellipses is ten.

19. The particle according to claim 17, wherein the given quantity of MacAdam ellipses is seven.

20. The particle according to claim 17, wherein the given quantity of MacAdam ellipses is four.

21. The particle according to claim 1, wherein the quantity of activator material comprises a thermal emission maximum quantity that is determined to limit a self-heating temperature change of the particle from a non-excited state to a steady-state excited condition.

22. The particle according to claim 1, wherein the activator material is combined with the host compound material in a quantity that limits a conversion efficiency of the luminescent compound to provide a given luminous intensity difference of the emission from a non-excited state to a steady-state excited condition combined with an emission of a light emitting source that emits the received light.

23. A method, comprising:
estimating a target temperature range corresponding to a temperature change of a luminescent particle that is attributable to thermal energy that is generated by a down-conversion of a portion of received light having a first dominant wavelength to emitting light having a second dominant wavelength that is different from the first dominant wavelength; and
estimating an upper limit of a quantity of activator material that is combined with a host compound material that corresponds to the target temperature range.

24. The method according to claim 23, wherein estimating the target temperature range comprises estimating the target temperature range using an estimated difference in luminous intensity of light emitted from the luminescent particle that corresponds to the temperature change of the luminescent particle that is attributable to thermal energy that is generated by the down-conversion of the portion of received light.

25. The method according to claim 23, wherein the upper limit of the quantity of activator material is less than about two mole percent.

26. The method according to claim 23, wherein the upper limit of the quantity of activator material corresponds to a reduced conversion efficiency that is less than a peak conversion efficiency that occurs with a greater quantity of activator material.

27. The method according to claim 23, wherein the host compound includes Ca₁₋ₓSrₓAlSiN₃, Ca₂Si₅N₈, Sr₂Si₅N₈, Ba₂Si₅N₈, BaSi₇N₁₀, BaYSi₄N₇, Y₅(SiO₄)₃N, Y₄Si₂O₇N₂, YSiO₂N, Y₂Si₃O₃N₄, Y₂Si₃-xAlxO₃+xN₄-x, Ca_{1.5}Si₉Al₃N₁₆, Y_{0.5}Si₉Al₃O_{1.5}N_{14.5}, CaSiN₂, Y₂Si₄N₆C, and/or Y₆Si₁₁N₂₀O, and
wherein the activator material includes at least one of Ce, Eu, Sm, Yb, Gd and/or Tb.

28. The method according to claim 23, wherein the host compound material comprises YAG and the activator material comprises less than about 2 mole percent Cerium.

29. The method according to claim 23, wherein the luminescent compound comprises a red nitride phosphor, and wherein the activator material includes less than about 0.2 mole percent Eu.

30. The method according to claim 23, wherein the luminescent compound comprises a BOSE type phosphor and wherein the activator material includes less than about 0.2 mole percent.

31. The method according to claim 23, wherein luminescent compound comprises a green-emitting phosphor including (Y₁₋ₓLuₓ)₃(Al_{1-y}Ga_{y})₅O₁₂:Ce where x and y include values in a range from about 0 to about 1.

32. The method according to claim 23, further comprising estimating a density of the luminescent particles relative to a specific light emitter to generate light at a given color point as a function of the upper limit of the quantity of activator material.

33. The method according to claim 23, further comprising doping the host compound with the activator material such that a color shift in a combined emission of the light of the first dominant wavelength and the second dominant wavelength is less than about 0.004 MacAdam ellipses in a two-dimensional color space defined by a 1931 CIE Chromaticity Diagram from an initial temperature of about 20 degrees C. to a steady state temperature of about 60 degrees C.

34. The method according to claim 23, further comprising doping the host compound with the activator material such that a color shift in a combined emission of the light of the first dominant wavelength and the second dominant wavelength is less than about 0.004 MacAdam ellipses in a two-dimensional color space defined by a 1931 CIE Chromaticity Diagram from an initial temperature of about 20 degrees C. to a steady state temperature of about 95 degrees C.

35. The method according to claim 23, further comprising doping the host compound with the activator material such that a color shift in a combined emission of the light of the first dominant wavelength and the second dominant wavelength is less than about 0.002 MacAdam ellipses in a two-dimensional color space defined by a 1931 CIE Chromaticity Diagram from an initial temperature of about 20 degrees C. to a steady state temperature of about 60 degrees C.

36. The method according to claim 23, further comprising doping the host compound with the activator material such that a color shift in a combined emission of the light of the first dominant wavelength and the second dominant wavelength is less than about 0.002 MacAdam ellipses in a two-dimensional color space defined by a 1931 CIE Chromaticity Diagram from an initial temperature of about 20 degrees C. to a steady state temperature of about 95 degrees C.

37. A light emitting device comprising:
a light emitting source that is configured to emit light having a first dominant wavelength; and
a plurality of luminescent particles, ones the plurality of luminescent particles including a luminescent compound that is configured to absorb a portion of light emitted from the light emitting source and to emit light having a second dominant wavelength that is different from the first dominant wavelength, the luminescent compound comprising:
a host compound material; and
an activator material that is combined with the host compound material in a quantity that limits a conversion efficiency of the luminescent compound to provide a given difference in an emission intensity from a non-excited state to a steady-state excited condition, the given difference corresponding to a color difference in a combined light emission that includes the light having the first dominant wavelength and the light having the second dominant wavelength, and
a silicone encapsulant in which the plurality of luminescent particles are dispersed.

38. The light emitting device according to claim 37, wherein the plurality of luminescent particles are configured to be in a receiving path of light emitted from the light emitting source.

39. The light emitting device according to claim 37,
wherein an upper limit of the quantity of activator material corresponds to a reduced conversion efficiency that is less than a peak conversion efficiency that occurs with a greater quantity of activator material.

40. The light emitting device according to claim 39, wherein the plurality luminescent particles are dispersed within the silicone encapsulant in a first density that corresponds to the reduced conversion efficiency, and
wherein the first density is greater than a second density that corresponds to the luminescent compound with a greater quantity of activator material than the upper limit.

41. The light emitting device according to claim 37, wherein the host compound includes Ca₁₋ₓSrₓAlSiN₃, Ca₂Si₅N₈, Sr₂Si₅N₈, Ba₂Si₅N₈, BaSi₇N₁₀, BaYSi₄N₇, Y₅(SiO₄)₃N, Y₄Si₂O₇N₂, YSiO₂N, Y₂Si₃O₃N₄, Y₂Si₃-xAlxO₃+xN₄-x, Ca_{1.5}Si₉Al₃N₁₆, Y_{0.5}Si₉Al₃O_{1.5}N_{14.5}, CaSiN₂, Y₂Si₄N₆C, and/or Y₆Si₁₁N₂₀O.

42. The light emitting device according to claim 37, wherein the activator material includes at least one of Ce, Eu, Sm, Yb, Gd and/or Tb.

43. The light emitting device according to claim 37, wherein the quantity of the activator material that is combined with the host compound material is less than about 2 mole percent to limit the conversion efficiency of the luminescent compound, to provide a given difference in an intensity of the emission from a non-excited state to a steady-state excited condition.

44. The light emitting device according to claim 37, wherein an emission color of the light emitting device is a combination of the first dominant wavelength and the second dominant wavelength.

45. The light emitting device according to claim 44, wherein the quantity of the activator material that is combined with the host compound material is less than about 2 mole percent to limit a change in the emission color of the light emitting device.

46. The light emitting device according to claim 37, wherein the plurality of luminescent particles includes a plurality of first luminescent particles that are configured to emit light having the second dominant wavelength and a plurality of second luminescent particles that are configured to emit light having a third dominant wavelength that is different from the first dominant wavelength.

47. A light emitting device comprising:
a plurality of luminescent particles, ones the plurality of luminescent particles including a luminescent compound that, when placed in a path of light having a first dominant wavelength, is configured to absorb a portion of the light emitted from the light emitting source and to emit light having a second dominant wavelength that is different from the first dominant wavelength, the luminescent compound comprising:
a host compound material; and
an activator material that is combined with the host compound material in a quantity that limits a conversion efficiency of the luminescent compound to provide a given color difference of the emission wavelength from a non-excited state to a steady-state excited condition.

48. The light emitting device according to claim 47, wherein the host compound material comprises a yttrium aluminum garnet phosphor (YAG) and wherein the activator material comprises Cerium.

49. The light emitting device according to claim 47, wherein the host compound material comprises a yttrium aluminum garnet phosphor (YAG) and wherein the activator material comprises less than about 2 mole percent Cerium.

50. The light emitting device according to claim 47, wherein the luminescent compound comprises a red nitride phosphor, and wherein the activator material comprises less than about 0.2 mole percent Eu.

51. The light emitting device according to claim 50, wherein the red nitride phosphor includes Ca_{1-x-y}SrₓEu_{y}AlSiN₃ where y includes a value that is less than about 0.002.

52. The light emitting device according to claim 50, wherein the red nitride phosphor includes Ca_{1-x-y}SrₓEu_{y}AlSiN₃ where y includes a value that is less than about 0.0015.

53. The light emitting device according to claim 47, wherein the luminescent compound comprises a BOSE type green-emitting phosphor and wherein the activator material includes less than about 0.2 mole percent.

54. The light emitting device according to claim 47, wherein the luminescent compound comprises a green-emitting phosphor including (Y₁₋ₓLuₓ)₃(Al_{1-y}Ga_{y})₅O₁₂:Ce where x and y include values in a range from about 0 to about 1.

55. The light emitting device according to claim 47, wherein the host compound material comprises a (Tb₁₋ₓREₓ)₃Al₅O₁₂:Ce phosphor (TAG) and wherein the activator material comprises less than about 0.2 mole percent Cerium.

56. The light emitting device according to claim 47, wherein the quantity of the activator material that is combined with the host compound material is less than about 2 mole percent to limit the conversion efficiency of the luminescent compound, to provide a given color shift of the emission wavelength from a non-excited state to a steady-state excited condition.

57. The light emitting device according to claim 47, wherein a first portion of the plurality of luminescent particles is configured to emit light corresponding to the second dominant wavelength and a second portion of the plurality of luminescent particles is configured to emit light having a third dominant wavelength that is different from the second dominant wavelength.
